(19) United States
(12) Patent Application Publication
(10) Pub. No.: US 2002/0195723 A1
(43) Pub. Date: Dec. 26, 2002

(54) Bond pad structure

(76) Inventor: Daniel Collette, Albuquerque, NM (US)

Correspondence Address: CORPORATE COUNSEL, PHILLIPS NORTH AMERICA CORPORATION, 580 WHITE PLAINS ROAD, TARRYTOWN, NY, 10591, US

(21) Appl. No.: 09/887,444

(22) Filed: Jun. 25, 2001

(51) Int. Cl. H01L 23/053; H01L 23/12; H01L 23/48; H01L 21/44; H01L 23/52; H01L 29/40

(52) U.S. Cl. 257/786; 257/784; 257/774; 257/700; 257/773; 257/758; 438/612

(57) ABSTRACT

A bond pad structure includes a bond pad, an underlying metal layer and an insulating layer, normally a passivation layer extending between the metal and bond pad layers, the passivation layer perforated. Preferably, the perforations are hexagonal to produce a hexagonal matrix. To reduce or avoid deformation of the matrix during bonding, the hexagons are oriented relative to the bond pad axis, for example at 15°.

This invention relates to bond pad structures, such as are used in semiconductor devices.

### BACKGROUND OF THE INVENTION

The technology of bond pad structure is well known, being used for the wire bonding of connector wires to bond pads on devices, such as dies. Problems arise during bonding of wires to bond pads in devices such as dies when active devices are incorporated under the bond pad site or sites. Cracking of one or more underlying layers can arise causing disruption of one or more active devices and other effects. Efforts have been made to avoid these problems by making process changes. Typical changes are the thickening of a metal layer, a passivation layer, or both. However, although some improvement can be obtained, problems still arise.

### SUMMARY OF THE PRESENT INVENTION

The present invention provides for the treatment of an underlying layer, a passivation layer, for example, to provide a perforated layer. The passivation layer is formed on the final metal layer and is covered by the bond pad layer. A convenient method of treating the passivation layer is by etching. There is provided a perforated matrix which is positioned between the two layers.

The preferred form of the perforated layer is in the form of an hexagonal matrix. To increase strength and resistance to collapse, the matrix is oriented at 15° relative to the axis of the bond pad. With such an arrangement, no one plane, or side of the hexagon is parallel to or perpendicular to the plane of bonding energy.

Thus broadly the invention provides a bond pad structure, comprising a perforated support layer over a metal layer, with a metal bond pad layer on the perforated layer and connecting through the perforated layer to the metal layer.

### BRIEF DESCRIPTION OF THE DRAWINGS

FIG. 1 is a plan view of part of a die, having a plurality of bond pads of known form;

FIG. 2 is a diagrammatic cross-section on line 2-2 of FIG. 1, illustrating a known form of structure;

FIG. 3 is a cross-section, similar to that of FIG. 2, but illustrating a structure in accordance with the present invention;

FIG. 4 is a cross-section through a device, such as a die, illustrating a structure as in the present invention in more detail;

FIG. 5 is a diagrammatic plan view of a bond pad, illustrating the orientation of the matrix relative to the bond pad axis; and

FIG. 6 is a plan view of a hexagonal matrix in a larger scale.

Illustrated in FIG. 1 is a plan view of a semiconductor device 10, for example a die, which can be mounted on a substrate 12. At various positions on the surface of the device 10 are formed bond pads 14. As illustrated in FIG. 2, each bond pad 14 is connected by a via 16 to metal layer 18, herein referred to, for convenience, as a first layer. The via 16 is formed and extends through a passivation layer 20, which can be an oxinitride or glass layer, for example.

A control wire 22 is bonded to the bond pad 14, at 24. A further passivation layer 26 is normally formed over the bond pads 14 and the top surface of the die. FIGS. 1 and 2 illustrate prior art.

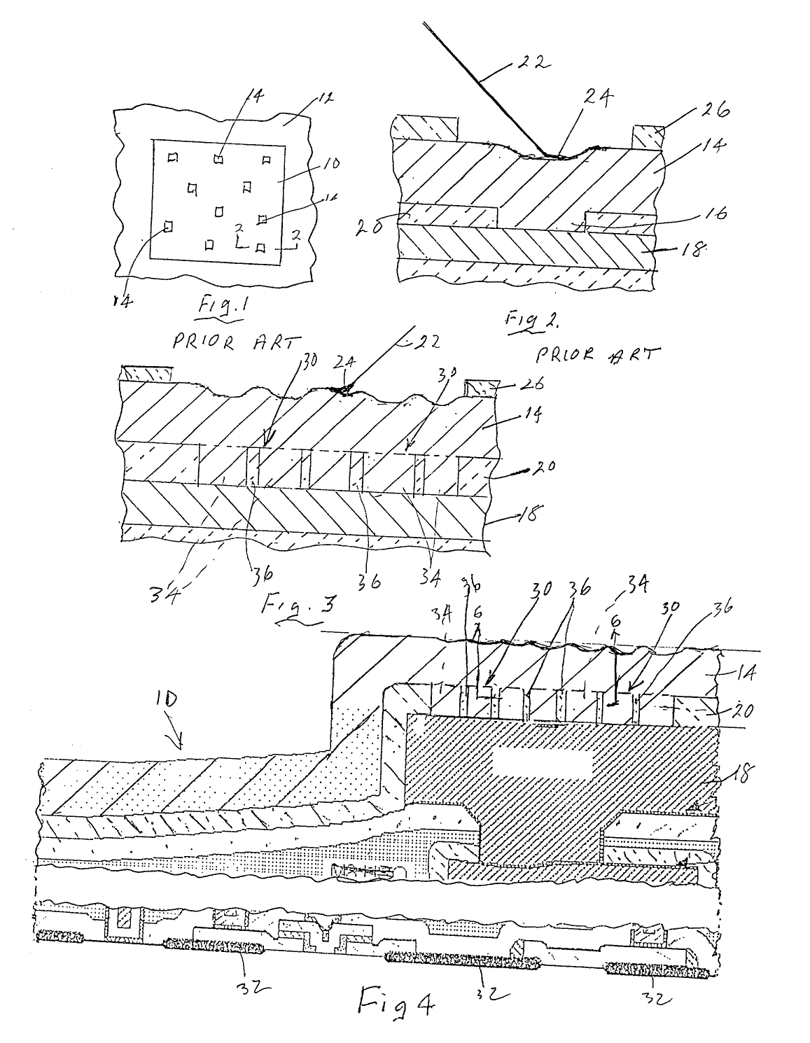

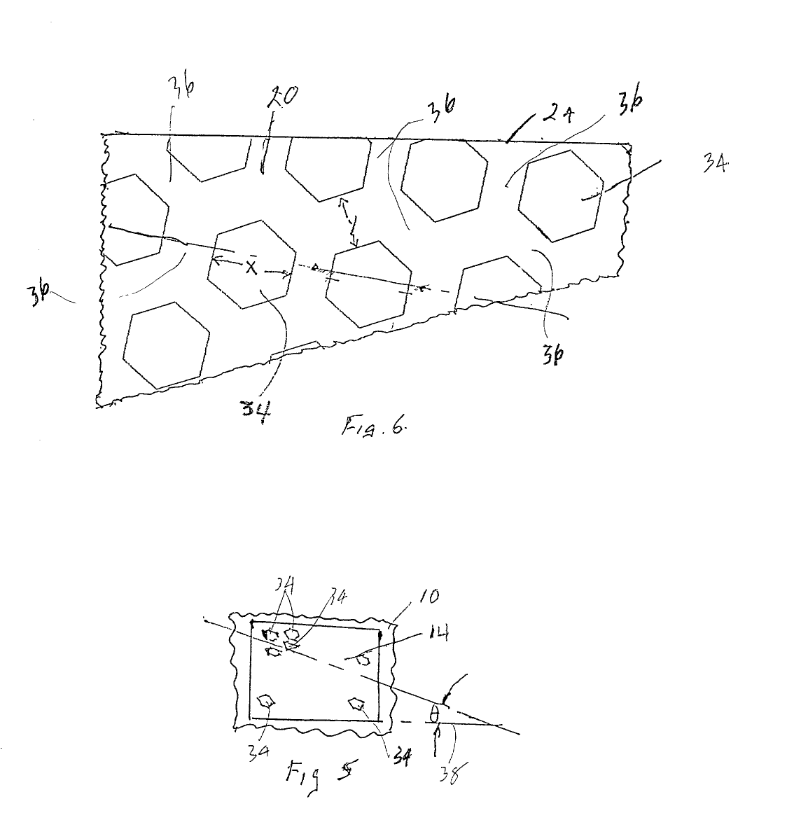

FIG. 3 is a cross-section, similar to that of FIG. 2, illustrating an hexagonal matrix 30 formed in the passivation layer 20 in accordance with the present invention. The material of the bond pad 14 extends through the matrix to connect with the layer 18. This structure is illustrated in FIG. 4, which is part of a die 10 to a much enlarged scale, showing active devices, etc. formed in the die. Contact pads 32 provide for mounting on a substrate. In FIG. 4 an overlying passivation layer is not shown but will normally be applied.

The matrix structure 30, in the drawings, has hexagonal perforations 34, with intervening walls 36.

FIG. 5 illustrates the orientation of the hexagon perforations 34 relative to the bond pad 14. As will be seen, the walls 36 of the hexagons are oriented at the angle θ relative to the axis 38, or side, of the bond pad.

FIG. 6 is a plan view, to a very large scale, illustrating part of the hexagonal matrix, being a section on the line 6-6 of FIG. 4.

Bonding of wires to the pads 14 is automated, using a thermosonic bonding—a combination of heat and ultrasonic bonding. The bond is made by a transducer which moves from pad to pad, very quickly. The transducer has a direction of movement which is generally parallel to the sides of a bond pad. Some movement of the transducer relative to the bond pad, can occur on initial contact between transducer and pad.

During application of the metal layer 14, the matrix 30 is not normally completely filled by the metal, although enough metal will penetrate through the matrix to provide a connection to metal layer 18. This allows some metal to be displaced into the matrix on bonding of the wire 22. The matrix provides an additional support, with some flexibility, and thus pressures and energies associated with bonding are dissipated.

The orientation of the matrix, to ensure no side surface of a hexagon is parallel or perpendicular to the plane of bonding energy and avoids possibility of collapse, while a strong support structure is provide.

The matrix is readily produced by masking and etching, that is by processes well known in the art of semiconductor production.

Other shapes of perforation can be used, for example circular or rectangular, but not all of the advantages of a hexagonal perforation are acquired. However sufficient improvement could be obtained to avoid cracking. Some variation in orientation of the perforations could assist in obtaining some advantages of the hexagon.

The dimensions of the matrix can vary considerably. For example, the dimension x in FIG. 6 can vary from 2μ to 25μ. The thickness of the matrix, that is the thickness of the passivation layer 20 can vary from 1.1μ to 4μ. The thickness at the walls, dimension y in FIG. 6, can vary from 2μ to 12μ. The thickness of the layer 14 can vary from 2μ to 3μ.

Thus there is provided a bond pad structure which has several advantages over existing structures. The matrix, or honeycomb, provides some additional support strength, and also provides space for displaced metal to flow. At the same time pressures and energy associated with the bonding procedure are displaced. While a hexagon shaped matrix or honeycomb is preferred, other shapes can be used. Orientation of a hexagon matrix avoids possible distortion of matrix walls due to the bonding energy.

Bonding pad structures, in accordance with the present invention, can be used at other positions on devices, including bonding on to substrates carrying devices.

What is claimed is:

1. A bond pad structure, for semiconductor devices, comprising a metal layer, a passivation layer extending over said metal layer and a metal bond pad, formed on said passivation layer, including perforations extending through the passivation payer beneath the bond pad to form a matrix, the bond pad extending through the perforations to contact the metal layer.

2. A bond pad structure as claimed in claim 1, said matrix etched in said passivation layer.

3. A bond pad structure as claimed in claim 1, said matrix composed of hexagonal perforations.

4. A bond pad structure as claimed in claim 3, said hexagonal perforations oriented relative to said bond pad.

5. A bond pad structure as claimed in claim 4, opposed sides of said hexagonal perforations oriented at about 15° relative to a side of a bond pad.

6. A bond pad structure as claimed in claim 4, said hexagonal perforations each of a dimension between side walls of between 2μ and 25μ.

7. A bond pad structure as claimed in claim 6, the thickness of the side walls between 2μ and 12μ.

8. A bond pad structure as claimed in claim 1, the thickness of the perforation layer being between 1.1μ to 4μ.

9. A semiconductor device comprising a die for mounting on a substrate, said die having a top surface, and a plurality of bond pads spaced on said top surface, at least one of said bond pads, having a structure comprising a metal layer, a passivation layer over the metal layer and a metal bond pad on said passivation layer, including a matrix formed by perforations extending through said passivation layer beneath the bond pad, the bond pad extending through the matrix to connect with the metal layer.

10. A device as claimed in claim 9, said matrix formed by hexagonal perforations.

11. A device as claimed in claim 10, said hexagonal perforations having sides oriented relative to sides of said bond pad.

12. A method of forming a bond pad structure for a semiconductor device having a metal layer, a passivation layer on the metal layer, comprising forming perforations in said passivation layer at a bond pad site, said perforations forming a matrix, and forming a metal bond pad on said passivation layer over said matrix, metal of said bond pad extending through said matrix to connect with said metal layer.

13. The method of claim 12, including etching said passivation layer to form said perforations.

14. The method of claim 12, including forming hexagonal perforations.

15. The method of claim 14, including orienting the perforations relative to the bond pad.

16. The method of claim 15, the perforations having sides, including orienting the sides at about 15° relative to sides of the bond pad.
